(19) United States
(12) Patent Application Publication
(10) Pub. No.: US 2026/0068763 A1
(43) Pub. Date: Mar. 5, 2026

(54) THREE-DIMENSIONAL STACKING FAN-OUT PACKAGING DEVICE AND PREPARATION METHOD FOR THREE-DIMENSIONAL STACKING FAN-OUT PACKAGING DEVICE

(71) Applicant: SHENZHEN XIUYUAN ELECTRONIC TECHNOLOGY CO., LTD., Shenzhen (CN)

(72) Inventors: Chuan HU, Shenzhen (CN); Xianwen CHEN, Shenzhen (CN)

(21) Appl. No.: 19/267,718

(22) Filed: Jul. 14, 2025

(30) Foreign Application Priority Data
Aug. 27, 2024 (CN) 2024111857290

(51) Int. Cl. H01L 25/18; H01L 21/48; H01L 21/56; H01L 21/683; H01L 23/00; H01L 23/053; H01L 23/31; H01L 23/538; H10B 80/00; H10D 80/30

(52) U.S. Cl. CPC H01L 25/18; H10B 80/00; H10D 80/30

(57) ABSTRACT

The present disclosure provides a three-dimensional stacking fan-out packaging device and a method for preparing a three-dimensional stacking fan-out packaging device, and relates to the field of chip packaging. In this device, the concave chip bonding area is defined by the pre-supported electrical connection frame; a plurality of first chips with functional surfaces towards the first direction and a plurality of second chips with functional surfaces towards the second direction are arranged in the chip bonding area; and the first stacking chip and the second stacking chip are arranged in a central symmetry or plane symmetry.

### CROSS-REFERENCE TO RELATED APPLICATION

The present disclosure claims priority to Chinese patent Application No. 2024111857290, filed with the Chinese Patent Office on Aug. 27, 2024, entitled “THREE-DIMENSIONAL STACKING FAN-OUT PACKAGING DEVICE AND PREPARATION METHOD FOR THREE-DIMENSIONAL STACKING FAN-OUT PACKAGING DEVICE”, the entire contents of which are incorporated herein by reference.

### TECHNICAL FIELD

The present disclosure relates to the field of wafer level package, and specifically to a three-dimensional stacking fan-out packaging device and a preparation method for the three-dimensional stacking fan-out packaging device.

### BACKGROUND ART

With the development of semiconductor technology, the package in the post-Moore's law era is pursued the higher transmission speed and smaller package size. Consequently, the package gradually develops towards high-speed signal transport, stacking, miniaturization, low cost, high reliability, heat dissipation, and others, for example, (1) high-speed signal transport: artificial intelligence, 5G, and other technologies need to improve semiconductor packaging technology when improving the speed of the chip, so as to improve the transmission speed; (2) stacking: one package shell contains only one chip in the past, but today, multiple chips can be stacked in one package shell by using multi-chip packaging (MCP), system in package (SiP), or other technologies; and (3) miniaturization: as semiconductor products are gradually used in mobile and even wearable products, the miniaturization is becoming an important requirement.

At the same time, there also have been some changes in the field of wire bonding. In some products, DRAM chips are stacked in one package and connected by using the wire bonding technology. Nowadays, the technology used by DRAM manufacturers develops from the wire bonding to flip chip packaging, so as to improve the I/O density of the chip. In turn, it will further drive the development of advanced packaging of memory chips.

Compared with the wire bonding and the flip chip technology, the fan-out technology is growing at a faster speed. The conventional fan-out technology includes a step of packaging a chip on a 200 mm or 300 mm wafer. In the panel-level fan-out, the package is processed on a large square panel, which increases the number of chips per substrate, so as to reduce manufacturing costs.

Meanwhile, a technology called chiplets is also emerging. With the chiplets, a system can be built like Lego blocks. The basic idea is that a modular chip menu is arranged in a wafer library; then different chips can be integrated into one package; and then they are connected by using a “die-to-die” interconnect solution.

At present, in order to increase the capacity of DRAM, the memory packaging primarily adopts 3D packaging of HBM (high bandwidth memory). The HBM employs the TSV direct stacking method, where in through silicon via (TSV) is the core process of HBM, and its cost accounts for nearly 30%, so as to be the highest part of the cost of the HBM packaging. Since the yield control and the cost of the TSV process are too high; the packaging process is complex; and the yield is difficult to control, the overall cost of the HBM is very high. As a result, it is currently limited to Al GPU packaging, and is difficult to extend to broader applications. Further, the staggered stacked chip structures have emerged. However, the number of chips that can be stacked is limited, and the integration is low, which is difficult to achieve High IO and fine pitch RDL. The conventional FAN-OUT technology is usually realized by forming the packaging body after the chips are stacked, and then the connection between distribution layers on two sides of the packaging body can be realized by using the method of forming a conductive post by electroplating after slotting the packaging body. By using the method of performing the plastic packaging after the stacking, on the one hand, the plastic packaging mold flow may cause a significant displacement of the stacked chips, which affects the structure stability and performance; and on the other hand, this method needs a higher slotting precision and a higher cost, and is easy to cause excessive slotting. Additionally, the main challenge in current FAN-OUT is warpage control, and especially during the Fan-Out panel-level process, it will often encounter the problem of warpage. The panel will probably generate a 2-3 mm warpage, and such a degree of bending will make the substrate and the chip have about a 10 mm gap. The wafer warpage will reduce the process accuracy of the subsequent mask lithography, which limits the improvement of the redistribution layer density. The stress generated by warpage is easy to concentrate at the interposer layer or solder joints, which results in cracking and falling off of the solder ball and separation of the intermediary layer.

### SUMMARY

The objects of the present disclosure include providing a three-dimensional stacking fan-out packaging device and a preparation method for a three-dimensional stacking fan-out packaging device, which can significantly reduce the costs and improve the yields, and at the same time ensure structural stability during the encapsulation process. Meanwhile, it adopts a symmetric coreless RDL structure, which has a very high chip-to-package ratio, and can significantly solve the problem of warpage during the manufacture and assembly process.

The embodiments of the present disclosure can be realized by the following ways.

In a first aspect, the present disclosure provides a three-dimensional stacking fan-out packaging device, including:
a pre-supported electrical connection frame, wherein the pre-supported electrical connection frame is configured to define a concave chip bonding area;
at least one group of first stacking chips arranged in the chip bonding area, wherein each group of the first stacking chips include a plurality of first chips with active surfaces facing a first direction;
at least one group of second stacking chips stacked on the first stacking chips, wherein each group of the second stacking chips include a plurality of second chips with active surfaces facing a second direction;
a packaging layer, wherein the packaging layer coats the first stacking chips, the second stacking chips, and the pre-supported electrical connection frame;
a first redistribution layer, wherein the first redistribution layer is located on one side of the packaging layer, and is electrically connected to the second chips and one end of the pre-supported electrical connection frame; and
a second redistribution layer, wherein the second redistribution layer is located on the other side of the packaging layer, and is electrically connected to the first chips and the other end of the pre-supported electrical connection frame, where in
the quantities of the first chips and the second chips are the same; the first direction and the second direction are opposite; the second stacking chips and the first stacking chips are arranged in a planar symmetry or plane symmetry; and the first redistribution layer and the second redistribution layer are electrically connected by the pre-supported electrical connection frame.

In an optional embodiment, the plurality of first chips are staggered and stacked, and the plurality of second chips are staggered and stacked.

In an optional embodiment, in each adjacent two of the first chips, a first chip departing from the first direction is arranged in a staggered manner in a third direction relative to the other first chip; and
in each adjacent two of the second chips, a second chip oriented away from the second direction is arranged in a staggered manner in a fourth direction relative to the other second chip, wherein
the third direction is opposite to the fourth direction.

In an optional embodiment, non-functional surfaces of the adjacent first chip and second chip are attached to each other, and the second chip is arranged relative to the adjacent first chip offset in the fourth direction.

In an optional embodiment, the non-functional surfaces of the adjacent first chip and second chip are attached to each other, and the second chip is attached relative to the adjacent first chip in an aligned configuration.

In an optional embodiment, the non-functional surfaces of the adjacent first chip and second chip are attached to each other, and the second chip is arranged relative to the adjacent first chip in the staggered manner in the third direction.

In an optional embodiment, the packaging layer includes a primary molding layer and a secondary molding layer, wherein the primary molding layer coats the second stacking chip, the pre-supported electrical connection frame, and a part of the first stacking chip, and the first redistribution layer is arranged to one side of the primary molding layer; and the secondary molding layer is arranged on the other side of the primary molding layer and encapsulates the rest of the first stacking chips, wherein the second redistribution layer is arranged on one side of the secondary molding layer away from the primary molding layer.

In an optional embodiment, a chip size of the first chip located in the secondary molding layer is larger than a chip size of the first chip located in the primary molding layer.

In an optional embodiment, the adjacent first chips are attached by a first die attach film (DAF); the adjacent second chips are attached by a second die attach film; and the adjacent first chip and second chip are attached by a third die attach film.

In an optional embodiment, primary pin pads are arranged on all functional surfaces of the plurality of first chips, wherein at least one first pin pad of each of the first chips is configured not to be obscured in the first direction by the other first chips, and the second redistribution layer is electrically connected to the first pin pads; and

second pin pads are arranged on all functional surfaces of the plurality of second chips, wherein at least one second pin pad of each of the second chips is configured not to be obscured in the second direction by the other second chips, and the first redistribution layer is electrically connected to the second pin pads.

In an optional embodiment, a plurality of first conductive posts raised towards the second direction are arranged on the first redistribution layer, wherein the plurality of first conductive posts are connected to the second pin pads on the plurality of second chips; and
a plurality of secondary conductive pillars extending towards the first direction are arranged on the second redistribution layer, wherein the second conductive posts are connected to the first pin pads on the plurality of first chips.

In an optional embodiment, the three-dimensional stacking fan-out packaging device further includes a photosensitive insulation layer arranged between the packaging layer and the second redistribution layer.

In an optional embodiment, a third conductive post extending towards the second direction is further arranged on the first redistribution layer, and the third conductive post is connected to one end of the pre-supported electrical connection frame; and a fourth conductive post raised towards the first direction is further arranged on the second redistribution layer, and the fourth conductive post is connected to the other end of the pre-supported electrical connection frame, wherein the first redistribution layer and the second redistribution layer are electrically connected by the pre-supported electrical connection frame.

In an optional embodiment, the pre-supported electrical connection frame includes:
a carrier filling enclosure, wherein the carrier filling enclosure is configured to define a chip attachment area, and a plated through hole (PTH) is formed by passing through the carrier filling enclosure; and
a filling conductive post, wherein the filling conductive post is filled in the plated through hole, and conductive pads are formed on two ends of the filling conductive post.

In an optional embodiment, a height of the carrier filling enclosure in the second direction is shorter than or equal to a stacking height of the first stacking chip and the second stacking chip.

In an optional embodiment, the plurality of first chips are precisely aligned stacking, and a plurality of first perforated conductive posts are arranged in the first chips departing from the second chips, wherein the first redistribution layer is electrically connected to the first chips by the first perforated conductive posts; and

the plurality of second chips are stacked in an aligning manner, and a plurality of second perforated conductive posts are arranged in the second chips departing from the first chips, wherein the second redistribution layer is electrically connected to the second chips by the second perforated conductive posts.

In a second aspect, the present disclosure provides a preparation method for a three-dimensional stacking fan-out packaging device for preparing the three-dimensional stacking fan-out packaging device as described in any one of the foregoing embodiments, wherein the preparation method includes:
preparing the pre-supported electrical connection frame;
attaching the pre-supported electrical connection frame on a temporary carrier, so that the pre-supported electrical connection frame defines the concave chip bonding area on the temporary carrier;
stacking the functional surfaces of the plurality of first chips on the chip bonding area towards the first direction, so as to form at least one group of the first stacking chips;
stacking the functional surfaces of the plurality of second chips on the first stacking chips towards the second direction, so as to form at least one group of the second stacking chips;
forming the packaging layer on the temporary carrier by molding, wherein the packaging layer coats the first stacking chips, the second stacking chips, and the pre-supported electrical connection frame;
preparing the first redistribution layer on one side of the packaging layer, wherein the first redistribution layer is electrically connected to the second chips and one end of the pre-supported electrical connection frame;
peeling off the temporary carrier and exposing the other side of the packaging layer; and
preparing the second redistribution layer on the other side of the packaging layer, wherein the second redistribution layer is electrically connected to the first chips and the other end of the pre-supported electrical connection frame, wherein
the first direction and the second direction are opposite, and the second stacking chip and the first stacking chip are arranged in a central symmetry or plane symmetry.

In an optional embodiment, the step of preparing the pre-supported electrical connection frame includes:
providing a molding material;
forming a plated through hole by passing through the molding material;
filling an electroplated metal or a conductive resin in the plated through hole to form the filling conductive post;
forming the conductive pads on two ends of the filling conductive post; and
removing a middle region of the molding material.

In a third aspect, the present disclosure provides a preparation method for a three-dimensional stacking fan-out packaging device for preparing the three-dimensional stacking fan-out packaging device as described in the foregoing embodiments, wherein the preparation method includes:
preparing the pre-supported electrical connection frame;
attaching the pre-supported electrical connection frame on a temporary carrier, so that the pre-supported electrical connection frame defines a concave chip bonding area on the temporary carrier;
stacking the functional surfaces of at least the first chips on the chip bonding area towards the first direction;
stacking the functional surfaces of the plurality of second chips on the first chips towards the second direction, so as to form the second stacking chip;
forming the primary molding layer on the temporary carrier by the plastic packaging, wherein the primary molding layer coats the second chips, the pre-supported electrical connection frame, and the first chips;
preparing the first redistribution layer on one side of the primary molding layer, wherein the first redistribution layer is electrically connected to the second chips and one end of the pre-supported electrical connection frame;
peeling off the temporary carrier and exposing the other side of the primary molding layer;
attaching at least one first chip on the other side of the primary molding layer, so that the first stacking chip is stacked by the plurality of first chips;
forming the secondary molding layer on the other side of the primary molding layer, wherein the secondary molding layer encapsulates the first chip externally; and
forming the secondary redistribution layer on one side of the second molding layer away from the primary molding layer, wherein the second redistribution layer is electrically connected to the first chips and the other end of the pre-supported electrical connection frame, wherein
the first direction and the second direction are opposite, and the second stacking chip and the first stacking chip are arranged in the central symmetry or plane symmetry.

The embodiments of the present disclosure include the following beneficial effects.

In the three-dimensional stacking fan-out packaging device provided by the embodiments of the present disclosure, the concave chip bonding area is defined by the pre-supported electrical connection frame; at least one group of first stacking chips are arranged in the chip bonding area, wherein the first stacking chip includes the plurality of first chips with functional surfaces towards the first direction, and the plurality of first chips are stacked; and at the same time, the second stacking chips are stacked on the first stacking chips, wherein the second stacking chip includes the plurality of second chips with functional surfaces towards the second direction, and the plurality of second chips are stacked. Later, after the packaging is finished by using the packaging layer, the routing is completed on two sides of the packaging layer, so as to form the first redistribution layer and the second redistribution layer. The first redistribution layer is electrically connected to the second chips; the second redistribution layer is electrically connected to the first chips; and the first redistribution layer and the second redistribution layer are electrically connected by the pre-supported electrical connection frame, so as to realize the integral electrical connection. Moreover, the first stacking chip and the second stacking chip are arranged in the central symmetry or plane symmetry. Compared with the prior art, the three-dimensional stacking fan-out packaging device provided by the embodiments of the present disclosure realizes the connection between the first redistribution layer and the second redistribution layer by using the pre-supported electrical connection frame, which can realize the routing interconnection without using the method of forming the conductive post by on site slotting and electroplating, which significantly reduces the cost and improves the yield. Meanwhile, the pre-supported electrical connection frame can play a structure support role, which prevents the significant displacement of the first chip or the second chip due to the mold flow since the flow tangential force of the plastic packaging material is too large when performing the plastic packaging, which ensures the structure stability and the device performance. Further, in the embodiments of the present disclosure, the stacked chips are staggered and the distribution layer and the chips are connected directly; meanwhile, a symmetric coreless RDL structure is used with a very high chip proportion; and the warpage is controlled very well, which can significantly solve the problem of warpage during the preparation process. It not only can greatly improve the yield and reliability when performing the wafer-level packaging, but also can directly implement Fine Pitch RDL, which can meet the needs of High IO and high density. The proposed design will offer advantages in the future Chiplet packaging, and can expand more applications on products.

### BRIEF DESCRIPTION OF DRAWINGS

In order to more clearly illustrate the technical solutions in the embodiments of the present disclosure, the following will briefly introduce the drawings to be used in the embodiments. It is to be understood that the following drawings illustrate only certain embodiments of the present invention, and therefore should not be regarded as a limitation of the scope. For persons of ordinary skill in the field, other relevant drawings can be obtained based on these drawings without inventive efforts.

FIG. 1 shows a schematic structure diagram of a three-dimensional stacking fan-out packaging device provided by an embodiment of the present disclosure;

FIG. 2 shows a sectional view of a pre-supported electrical connection frame in FIG. 1;

FIG. 3 shows a top view of a pre-supported electrical connection frame in FIG. 1;

FIG. 4 shows a schematic structure diagram of another three-dimensional stacking fan-out packaging device provided by an embodiment of the present disclosure;

FIG. 5 to FIG. 11 show process flow diagrams of a preparation method for a three-dimensional stacking fan-out packaging device provided by an embodiment of the present disclosure;

FIG. 12 shows a schematic structure diagram of another three-dimensional stacking fan-out packaging device provided by an embodiment of the present disclosure;

FIG. 13 to FIG. 14 show process flow diagrams of a preparation method for another three-dimensional stacking fan-out packaging device provided by an embodiment of the present disclosure;

FIG. 15 shows a schematic structure diagram of another three-dimensional stacking fan-out packaging device provided by an embodiment of the present disclosure;

FIG. 16 to FIG. 22 show process flow diagrams of a preparation method for another three-dimensional stacking fan-out packaging device provided by an embodiment of the present disclosure; and

FIG. 23 to FIG. 27 show process flow diagrams of another preparation method for another three-dimensional stacking fan-out packaging device provided by an embodiment of the present disclosure;

Reference numbers: 100—three-dimensional stacking fan-out packaging device; 110—pre-supported electrical connection frame; 111—carrier filling enclosure; 112—plated through hole; 113—filling conductive post; 114—conductive pad; 120—first stacking chip; 121—first chip; 1211—first perforated conductive post; 122—first die attach film; 123—first pin pad; 130—second stacking chip; 131—second chip; 132—second die attach film; 133—third die attach film; 134—second pin pad; 140—packaging layer; 141—primary molding layer; 143—secondary molding layer; 150—first redistribution layer; 151—first conductive post; 152—third conductive post; 160—second redistribution layer; 161—second conductive post; 162—fourth conductive post; 170—photosensitive insulating layer; and 200—temporary carrier.

### DETAILED DESCRIPTION OF EMBODIMENTS

In order to make the purpose, technical solutions, and advantages of the embodiments of the present disclosure clearer, the technical solutions in the embodiments of the present disclosure will be clearly and completely described in conjunction with the drawings in the embodiments of the present disclosure. It is clear that the embodiments described are partial embodiments of the present disclosure, but not all of the embodiments. The components in the embodiments of the present disclosure generally described and shown in the drawings herein may be arranged and designed in multiple different configurations.

Therefore, the following detailed description of embodiments of the present disclosure provided in the drawings is not intended to limit the scope of the present disclosure for which protection is claimed, but rather represents only selected embodiments of the present disclosure. Based on the embodiments in the present disclosure, all other embodiments obtained by a person of ordinary skill in the art without making creative labor fall within the scope of protection of the present disclosure.

It should be noted that similar symbols and letters denote similar items in the following drawings, so that once an item is defined in a drawing, no further definition or explanation is required in the subsequent drawings.

In the description of the present disclosure, it should be noted that the orientation or position relationship indicated by the terms, “up”, “down”, “inside”, “outside”, etc., is the orientation or position relationship based on the drawings, or is the orientation or position relationship of the product of the present disclosure customarily placed in use, which are only to facilitate the description of the present disclosure and simplify the description, and are not to indicate or imply that the device or element referred to must have a particular orientation, or be constructed and operated with a particular orientation, and therefore cannot to be understood as limitations of the present disclosure.

Additionally, the terms “first”, and “second”, etc., are used only to differentiate the description, and are not to be understood as indicating or implying relative importance.

In the text, the term “chip” refers to any type of semiconductor chip or integrated circuit chip that realizes a specific function, and also refers to any type of semiconductor die or integrated circuit die that realizes a specific function.

In the text, the term “functional surface” refers to the surface of the chip provided with a chip pin pad, and the term “non-functional surface” refers to the other surface opposite to the functional surface.

As disclosed in the background art, the 3D packaging technology of HBM in the prior art usually adopts a TSV direct stacking method, and the chips are electrically connected by TSV plated through holes. Therefore, the through silicon via (TSV) is the core process of HBM, and its cost accounts for nearly 30%, so as to be the highest part of the cost of the HBM packaging. The yield control is difficult and the cost of the TSV process is too high; the packaging process is complex; and the yield is difficult to control, which results in a very high cost of the overall HBM cost.

Further, the staggered stacked chip structure occurs. However, the stacked amounts of chips are limited, and the integration is low, which is difficult to realize the High IO and the fine pitch RDL. The conventional FAN-OUT technology is usually realized by forming the packaging body after the chips are stacked, and then the connection between distribution layers on two sides of the packaging body can be realized by using the method of forming a conductive post by electroplating after slotting the packaging body. By using the method of performing the plastic packaging after the stacking, on the one hand, the plastic packaging mold flow may cause a significant displacement of the stacked chips, which affects the structure stability and performance; and on the other hand, this method needs a higher slotting precision, has a higher cost, and is easy to cause excessive slotting.

Moreover, the biggest problem of the current FAN-OUT is warpage control, and especially when performing the Fan-Out panel level process, it will often encounter the problem of warpage. The panel will probably generate a 2-3 mm warpage, and such a degree of bending will make the substrate and the chip have about a 10 mm gap. The wafer warpage will reduce the process accuracy of the subsequent mask lithography, which limits the improvement of the redistribution layer density. The stress generated by warpage is easy to concentrate at the interposer layer or the solder joints, which results in cracking and falling off of the solder ball and delamination of the interposer layer.

In order to solve the above problems, the embodiments of the present disclosure provide a three-dimensional stacking fan-out packaging device 100. It is to be noted that various features in the embodiments of the present disclosure can be combined with each other without conflict.

Referring to FIG. 1, the embodiment of the present disclosure provides a three-dimensional stacking fan-out packaging device 100, which can realize the routing interconnection without forming the conductive post by on site slotting and electroplating, which significantly reduces the cost and improves the yield, and can avoid the chip displacement caused by the mold flow. Meanwhile, the symmetric coreless RDL structure is used, and has the very high chip proportion, which significantly minimizes warpage during manufacturing while enabling high IO density and fine-pitch redistribution layers (RDLs). Compared with the 3D structure of the current HBM, it can have the same chip stacking density, and can have more IOs. In the above design, more-layer chip stacking has been taken into account. Since the warpage is very small, the packaging of PoP can be directly implemented, which effectively expands the memory capacity, and also can integrate other controllers and NPU/GPU, so to realize the packaging of Chiplet. The warpage is controlled very well, and it can also directly expand to the panel-level packaging, which significantly reduces the cost.

The embodiment of the present disclosure provides a three-dimensional stacking fan-out packaging device 100, including a pre-supported electrical connection frame 110, at least one group of first stacking chips 120, at least one group of second stacking chips 130, a packaging layer 140, a first redistribution layer 150, and a second redistribution layer 160. The pre-supported electrical connection frame 110 is configured to define a concave chip bonding area, which facilitates the subsequent attachment. The at least one group of first stacking chips 120 are arranged in the chip bonding area, wherein each group of the first stacking chips 120 include the plurality of first chips 121 with functional surfaces towards the first direction, and the plurality of first chips 121 are staggered and stacked. The at least one group of second stacking chips 130 are stacked on the first stacking chips 120, wherein each group of the second stacking chips 130 include the plurality of second chips 131 with functional surfaces towards the second direction, and the plurality of second chips 131 are staggered and stacked. The packaging layer 140 coats the first stacking chips 120, the second stacking chips 130, and the pre-supported electrical connection frame 110. The first redistribution layer 150 is located on one side of the packaging layer 140, and is electrically connected to the second chips 131 and one end of the pre-supported electrical connection frame 110; and the second redistribution layer 160 is located on the other side of the packaging layer 140, and is electrically connected to the first chips 121 and one end of the pre-supported electrical connection frame 110. The amounts of the first chips 121 and the second chips 131 are the same; the first direction and the second direction are opposite; the second stacking chips 130 and the first stacking chips 120 are arranged in the central symmetry or plane symmetry; and the first redistribution layer 150 and the second redistribution layer 160 are electrically connected by the pre-supported electrical connection frame 110.

It should be noted that herein, the term “first direction” is a direction consistent with the stacking direction of the plurality of chips, i.e., the direction from bottom to top shown in the figures; and the term “second direction” is a direction departing from the stacking direction of the plurality of chips, i.e., the direction from top to bottom shown in the figure. Therefore, it can be understood that when the stacking direction of the chips is changed, the directions referred to by the first direction and the second direction will also be changed accordingly, i.e., the “first direction” and the “second direction” should not be limited to a particular direction shown in the figures. The stacking direction of the chips refers to the direction along which the chips are stacked layer by layer, so that the height of the stacking chip increases gradually.

In the three-dimensional stacking fan-out packaging device 100 provided by the embodiment of the present disclosure, the concave chip bonding area is defined by the pre-supported electrical connection frame 110; at least one group of first stacking chips 120 are arranged in the chip bonding area, wherein the first stacking chips 120 include the plurality of first chips 121 with functional surfaces towards the first direction, and the plurality of first chips 121 are staggered and stacked; and at the same time, the second stacking chip 130 is stacked on the first stacking chips 120, wherein the second stacking chip 130 includes the plurality of second chips 131 with functional surfaces towards the second direction, and the plurality of second chips 131 are staggered and stacked. Later, after the packaging is finished by using the packaging layer 140, the routing is completed on two sides of the packaging layer 140, so as to form the first redistribution layer 150 and the second redistribution layer 160. The first redistribution layer 150 is electrically connected to the second chips 131; the second redistribution layer 160 is electrically connected to the first chips 121; and the first redistribution layer 150 and the second redistribution layer 160 are electrically connected by the pre-supported electrical connection frame 110, so as to realize the integral electrical connection. Moreover, the first stacking chip and the second stacking chip 130 are arranged in the central symmetry or plane symmetry. In the embodiment of the present disclosure, the first redistribution layer 150 is connected to the second redistribution layer 160 by using the pre-supported electrical connection frame 110, which can realize the routing interconnection without using the method of forming the conductive post by on site slotting and electroplating, which significantly reduces the cost and improves the yield. Meanwhile, the pre-supported electrical connection frame 110 can play a structure support role, which prevents the significant displacement of the first chip 121 or the second chip 131 due to the mold flow since the flow tangential force of the plastic packaging material is too large when performing the plastic packaging, which ensures the structure stability and the device performance. Meanwhile, the symmetric coreless RDL structure is used with a very high chip proportion; and the warpage is controlled very well, which can significantly solve the problem of warpage during the preparation process. It not only can greatly improve the yield and reliability when performing the wafer-level packaging, but also can directly implement Fine Pitch RDL, which can meet the needs of High IO and high density. It will have advantages in the future Chiplet packaging, and can expand more applications on products.

Referring to FIG. 1, in some embodiments, in each adjacent two of the first chips 121, the first chip 121 departing from the second direction is arranged in a staggered manner in a third direction relative to the other first chip 121; and in each adjacent two of the second chips 131, the second chip 131 departing from the second direction is arranged in a staggered manner in a third direction relative to the other second chip 131. Specifically, the plurality of first chips 121 are sequentially staggered and stacked along a single direction, wherein the stagger direction is the third direction, and the upper chip of each adjacent two of the first chips 121 is staggered towards the third direction; and the plurality of second chips 131 are sequentially staggered and stacked along a single direction, wherein the stagger direction is the third direction, and the upper chip of each adjacent two of the second chips 131 is staggered towards the third direction.

Further, in some embodiments, non-functional surfaces of the adjacent first chip 121 and second chip 131 are attached to each other, and the second chip 131 is arranged relative to the adjacent first chip 121 in the staggered manner in the fourth direction. Specifically, the non-functional surface of the second chip 131 located at the most bottom layer and the non-functional surface of the first chip 121 located at the top layer are attached to each other, so that the second stacking chip 130 and the first stacking chip 120 are stacked. Moreover, the second chip 131 is staggered relative to the first chip 121 in the fourth direction, so that the plurality of first chips 121 and the plurality of second chips 131 form a centrally symmetric structure. By adopting the symmetric structure, it can realize the multi-layer stacking, so as to improve the stacking density; and at the same time, the symmetric structure can further effectively balance the internal stress, so as to effectively reduce the warpage.

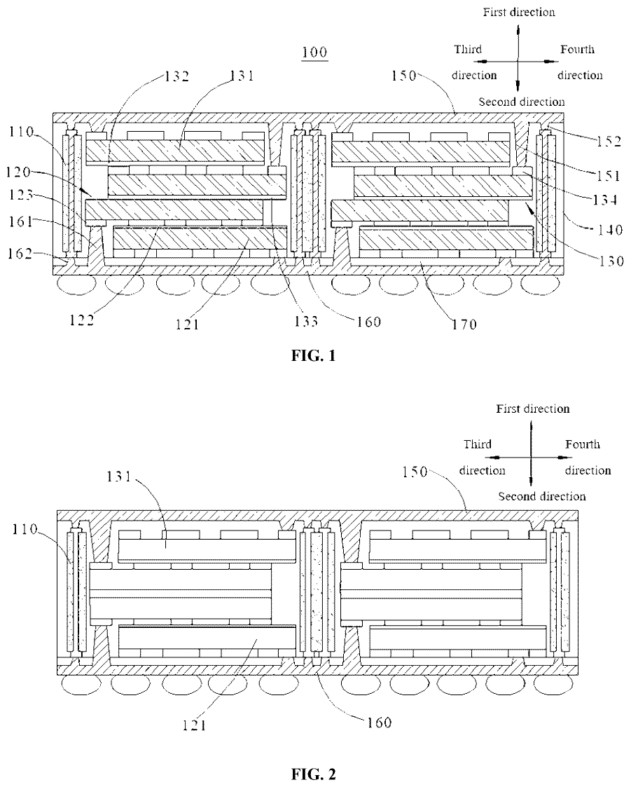

Referring to FIG. 2, in some other embodiments, in each adjacent two of the first chips 121, the first chip 121 departing from the second direction is arranged in a staggered manner in the third direction relative to the other first chip 121; and in each adjacent two of the second chips 131, the second chip 131 departing from the second direction is arranged in a staggered manner in the fourth direction relative to the other second chip 131, wherein the third direction and the fourth direction are opposite. Specifically, the plurality of first chips 121 are sequentially staggered and stacked along a single direction, wherein the stagger direction is the third direction, and the upper chip of each adjacent two of the first chips 121 is staggered towards the third direction; and the plurality of second chips 131 are sequentially staggered and stacked along a single direction, wherein the stagger direction is the fourth direction, and the upper chip of each adjacent two of the second chips 131 is staggered towards the fourth direction.

Further, in some embodiments, the non-functional surfaces of the adjacent first chip 121 and second chip 131 are attached to each other, and the second chip 131 and the adjacent first chip 121 are attached relatively in an alignment manner. Specifically, the non-functional surface of the second chip 131 located at the most bottom layer and the non-functional surface of the first chip 121 located at the top layer are attached to each other, so that the second stacking chip 130 and the first stacking chip 120 are stacked. Moreover, the second chip 131 and the first chip 121 are attached relatively in the alignment manner, i.e., the second chip 131 and the first chip 121 adopt an alignment stacking structure, so that the plurality of first chips 121 and the plurality of second chips 131 form a plane symmetric structure. By adopting the symmetric structure, it can realize the multi-layer stacking, so as to improve the stacking density; and at the same time, the symmetric structure can further effectively balance the internal stress, so as to effectively reduce the warpage.

Of course, in other preferred embodiments of the present disclosure, the plurality of first chips 121 can also be staggered and stacked in the fourth direction; the plurality of second chips 131 can also be staggered and stacked in the third direction; and there is no specific limitation to the staggered stacking directions of the first chips 121 and the second chips 131.

In some other embodiments, the non-functional surfaces of the adjacent first chip 121 and second chip 131 are attached to each other, and the second chip 131 is arranged relative to the adjacent first chip 121 in the staggered manner in the third direction.

It is to be noted that in the text, the term “third direction” is a direction that translates in the horizontal direction and is gradually away from the side wall of one side of the pre-supported electrical connection frame 110, i.e., it can be the direction from left to right shown in the figures; and the term “fourth direction” is a direction that translates in the horizontal direction and is gradually away from the side wall of the other side of the pre-supported electrical connection frame 110, i.e., it can be the direction from right to left shown in the figures. Therefore, it can be understood that when the arrangement direction of the pre-supported electrical connection frame 110 is changed, the directions referred to by the third direction and the fourth direction will also be changed accordingly, i.e., the “third direction” and the “fourth direction” should not be limited to the particular direction shown in the figures.

Referring to FIG. 1, in some embodiments, the adjacent first chips 121 are attached by a first die attach film 122; the adjacent second chips 131 are attached by a second die attach film 132; and the adjacent first chip 121 and second chip 131 are attached by a third die attach film 133. Specifically, in actual attachment, the first die attach film 122 can be attached to the non-active surface of the bottom first chip 121; the second die attach film 132 can be attached to the non-active surface of the bottom second chip 131; and the third die attach film 133 can be attached to the non-active surface of the top first chip 121, wherein the first die attach film 122, the second die attach film 132, and the third die attach film 133 are made by the same material, which can be the chip bonding adhesive of the high heat-dissipation material, such as silicone grease.

It is to be noted that the first chip 121 and the second chip 131 in the embodiments of the present disclosure both can be memory chips; the first chip 121 located at the lowest layer can further be a control chip; and there is no specific limitation herein to the specific types of the first chip 121 and the second chip 131.

In some embodiments, first pin pads 123 are arranged on all functional surfaces of the plurality of first chips 121, wherein at least one first pin pad 123 of each of the first chips 121 is configured not to be obscured in the first direction by other first chips 121, and the second redistribution layer 160 is electrically connected to the first pin pads 123; and second pin pads 134 are arranged on all functional surfaces of the plurality of second chips 131, wherein at least one second pin pad 134 of each of the second chips 131 is configured not to be obscured in the second direction by other second chips 131, and the first redistribution layer 150 is electrically connected to the second pin pads 134. Specifically, since the plurality of first chips 121 are staggered and the functional surfaces of the first chips 121 are towards the first direction, the functional surface of each first chip 121 has partial region directly exposed to the second redistribution layer 160. At least one first pin pad 123 can be arranged in this region, and the second redistribution layer 160 is electrically connected to the first pin pad 123. Similarly, since the plurality of second chips 131 are staggered and the functional surfaces of the second chip 131 are towards the second direction, the functional surface of each second chip 131 has partial region directly exposed to the first redistribution layer 150. At least one second pin pad 134 can be arranged in this region, and the first redistribution layer 150 is electrically connected to the second pin pad 134. The at least patrial functional surface of the first chip 121 faces the second redistribution layer 160, and the at least partial functional surface of the second chip 131 faces the first redistribution layer 150, which can realize the high-density routing and pad design, so as to realize high IO and to achieve Fine pitch RDL (fine pitch redistribution layer).

In some embodiments, a plurality of first conductive posts 151 raised towards the second direction are arranged on the first redistribution layer 150, wherein the plurality of first conductive posts 151 are connected to the second pin pads 134 on the plurality of second chips 131; and a plurality of second conductive posts 161 raised towards the first direction are arranged on the second redistribution layer 160, wherein the second conductive posts 161 are connected to the first pin pads 123 on the plurality of first chips 121. Specifically, the first conductive post 151 and the second conductive post 161 can be copper columns. During the actual preparation, the first conductive post 151 and the second conductive post 161 can be formed by wiring, and electrocoating copper columns, etc. Further, the first chip 121 is connected to the second redistribution layer 160 by the second conductive post 161, and the second chip 131 is connected to the first redistribution layer 150 by the first conductive post 151.

Further, the three-dimensional stacking fan-out packaging device 100 further includes a photosensitive insulating layer arranged 170 between the packaging layer 140 and the second redistribution layer 160. Specifically, the photosensitive insulating layer 170 is provided. On the one hand, the exposed chip pins on the packaging layer 140 can be covered; and a pattern opening can be formed by exposure development slotting; and the second redistribution layer 160 is electrically connected to the chip pins by an electroplated copper layer; and on the other hand, the photosensitive insulating layer 170 can electrically isolate the second redistribution layer 160 from the chip pins of the non-patterned opening region to prevent the leakage current.

In some embodiments, a third conductive post 152 raised towards the second direction is further arranged on the first redistribution layer 150, and the third conductive post 152 is connected to one end of the pre-supported electrical connection frame 110; and a fourth conductive post 162 raised towards the first direction is further arranged on the second redistribution layer 160, and the fourth conductive post 162 is connected to the other end of the pre-supported electrical connection frame, wherein the first redistribution layer 150 and the second redistribution layer 160 are electrically connected by the pre-supported electrical connection frame 110. Specifically, the third conductive post 152 and the fourth conductive post 162 can be prepared by electroplating the copper layer, and the third conductive post 152 can be arranged on the packaging layer 140. Specifically, the packaging layer 140 can be slotted to expose one end of the pre-supported electrical connection frame 110; then the third conductive post 152 is formed by electroplating within the slot opening; and then the first redistribution layer 150 can be prepared, so that the first redistribution layer 150 is electrically connected to the pre-supported electrical connection frame 110 by the third conductive post 152. The fourth conductive post 162 can be arranged on the photosensitive insulating layer 170. Specifically, the photosensitive insulating layer 170 can be slotted to expose the other end of the pre-supported electrical connection frame 110; then the fourth conductive post 162 is formed by electroplating within the slot opening; and then the second redistribution layer 160 can be prepared, so that the second redistribution layer 160 is electrically connected to the pre-supported electrical connection frame 110 by the fourth conductive post 162.

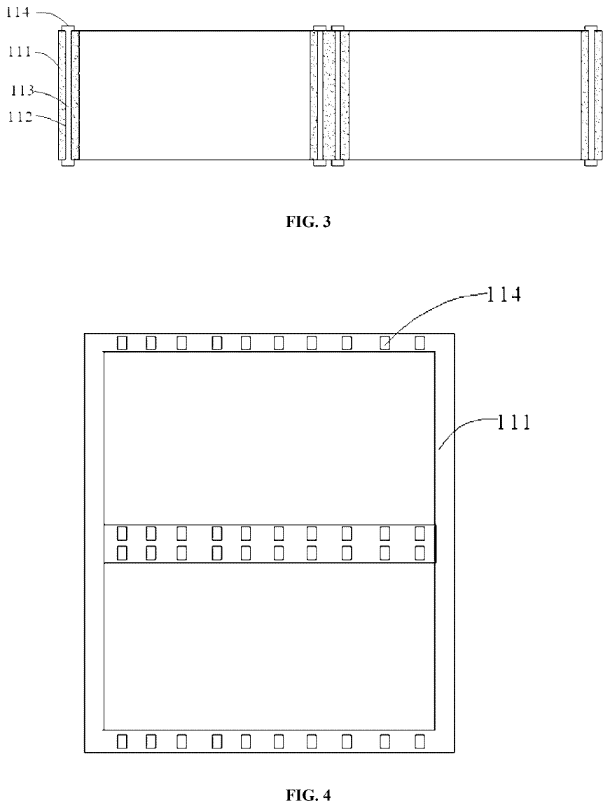

Referring to FIG. 3 and FIG. 4, in some embodiments, the pre-supported electrical connection frame 110 includes a carrier filling enclosure 111 and a filling conductive post 113, wherein the carrier filling enclosure 111 is configured to define a chip attachment area, and a plated through hole 112 is formed by passing through the carrier filling enclosure 111; and the filling conductive post 113 is filled in the plated through hole 112, and conductive pads 114 are formed on two ends of the filling conductive post 113. Specifically, the carrier filling enclosure 111 can be made of an insulating material, such as FR4, BT, and ABF, and its dielectric constant can be smaller than that of the packaging layer 140, so that the carrier filling enclosure 111 has better the high-frequency insulation performance and signal integrity, and the leakage current of the conductive post is also reduced. The filling conductive post 113 can be made of a metallic material or another conductive medium, e.g., the filling metallic post can be formed by electroplating a metallic layer within the plated through hole 112.

It should be noted that a pre-supported bracket in the embodiment can be prepared in advance, which simplifies the process; and the filling conductive post 113 has a higher arrangement accuracy which does not need to slot after packaging. Meanwhile, the carrier filling enclosure 111 is constructed as a frame, which can define the chip attachment area in advance. When performing the packaging after the first chips 121 and the second chips 131 are stacked, the flow of plastic packaging material will be constrained, which prevents the displacement caused by the first chips 121 or the second chips 131 due to the mold flow since the flow tangential force of the plastic packaging material is too large, which ensures the structure stability and the device performance. Additionally, the arrangement of the pre-supported bracket can further play a role of supporting the skeleton, which enhances the overall structure strength of the packaging layer 140, avoids the warpage phenomenon of the plastic packaging, and avoids the separation of the distribution layer.

In some embodiments, a height of the carrier filling enclosure 111 in the second direction is shorter than or equal to a stacking height of the first stacking chip 120 and the second stacking chip 130. Specifically, the height of the carrier filling enclosure 111 is relatively low. During routing, the second redistribution layer 160 can be connected to the conductive pad 114 at one end of the filling conductive post 113 by the fourth conductive post 162, and the first redistribution layer 150 can be connected to the conductive pad 114 at the other end of the filling post by the third conductive post 152. Since the packaging layer 140 is completely packaged outside the carrier filling enclosure 111, it has a sufficient thickness to prepare the first distribution layer, which avoids the step of providing the insulating medium layer additionally.

The embodiments of the present disclosure also provide a preparation method for the three-dimensional stacking fan-out packaging device 100 for preparing the three-dimensional stacking fan-out packaging device 100 in FIG. 1. The preparation method includes the following steps:

S1: preparing the pre-supported electrical connection frame 110.

Referring to FIG. 3, specifically, the pre-supported electrical connection frame 110 can be prepared in advance. During the actual preparation, a molding material can be provided first, wherein the molding material can be constructed by a substrate or substrate, and made of insulating materials such as FR4, BT, and ABF, and then the molding material is opened and passed through to form a plated through hole 112. Specifically, the position of forming the hole can be set according to the subsequent positioning area of attaching chips; and the process of forming the hole can be laser slotting, or can also be etching slotting. Through optimizing the slotting process and selecting a relative special material, the whole plated through hole 112 can be in a right-angled through hole shape, which ensures the filling conductive post 113 by subsequent molding is in a straight-post shape, so as to ensure its electrical connection performance. After opening the hole, an electroplated metal or a conductive resin can be filled into the plated through hole 112 to form the filling conductive post 113, wherein the conductive resin can be electrically conductive by adding conductive particles, and preferably an electroplating copper layer can be selected to form the filling conductive post 113. Later, the conductive pads 114 are formed at two ends of the filling conductive post 113, and the conductive pads 114 can cover the plated through hole 112. Finally, the middle region of the molding material is removed. Specifically, the excess molding material can be removed by using the etching process, so as to form the carrier filling enclosure 111, wherein the position and the size of the removed region can be defined according to the position of the plated through hole 112.

In other preferred embodiments of the present disclosure, the excess molding material can also be removed first, wherein the removal area can be arranged according to the size of the subsequent attachment area; and then the filling conductive post 113 is formed by forming the hole and electroplating, and this arrangement method can improve the precision of forming the hole.

S2: attaching the pre-supported electrical connection frame 110 on a temporary carrier 200, so that the pre-supported electrical connection frame 110 defines a concave chip bonding area on the temporary carrier 200.

Referring to FIG. 5, specifically, an adhesive film layer (UV adhesive) can be formed on the temporary carrier 200 first by a spin-coating process, and the adhesive film layer can be peeled off by a subsequent debonding process. Since the carrier filling enclosure 111 is in a frame construction, the pre-supported electrical connection frame 110 can be fixed by being directly aligned and attached to the temporary carrier 200, and the concave chip bonding area can be formed by the carrier filling enclosure 111.

S3: staggering and stacking the functional surfaces of the plurality of first chips 121 on the chip bonding area towards the first direction, so as to form at least one group of the first stacking chips 120.

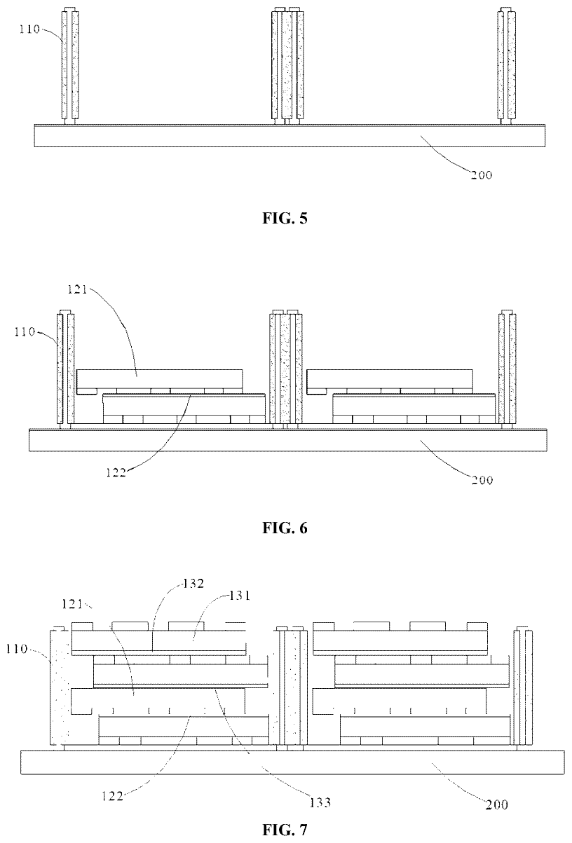

Referring to FIG. 6, specifically, two first chips 121 are illustrated herein as an example. First, the non-functional surface of one of the first chips 121 is coated or attached with the first die attach film 122; then the functional surface is attached to the temporary carrier 200 in the chip bonding area; and then the functional surface of the other first chip 121 is staggered and attached to the non-functional surface of the previous first chip 121 in the third direction, so as to complete the attachment of the first stacking chip 120.

S4: staggering and stacking the functional surfaces of the plurality of second chips 131 on the first stacking chips 120 towards the second direction, so as to form at least one group of the second stacking chips.

Referring to FIG. 7, specifically, two second chips 131 are illustrated herein as an example. First, the non-functional surface of one of the second chips 131 is coated or attached with the third die attach film 133; then its functional surface is staggered and attached to the non-functional surface of the first chip 121 located on the top layer in the fourth direction; and then the non-functional surface of the other second chip 131 is attached with the second die attach film 132, and the other second chip 131 is staggered and attached to the non-functional surface of the previous second chip 131 in the third direction, so as to complete the attachment of the second stacking chip 130.

The first direction and the second direction are opposite, and the second stacking chip 130 and the first stacking chip 120 are arranged in a central symmetry or plane symmetry.

S5: forming the packaging layer 140 on the temporary carrier 200 by plastic packaging.

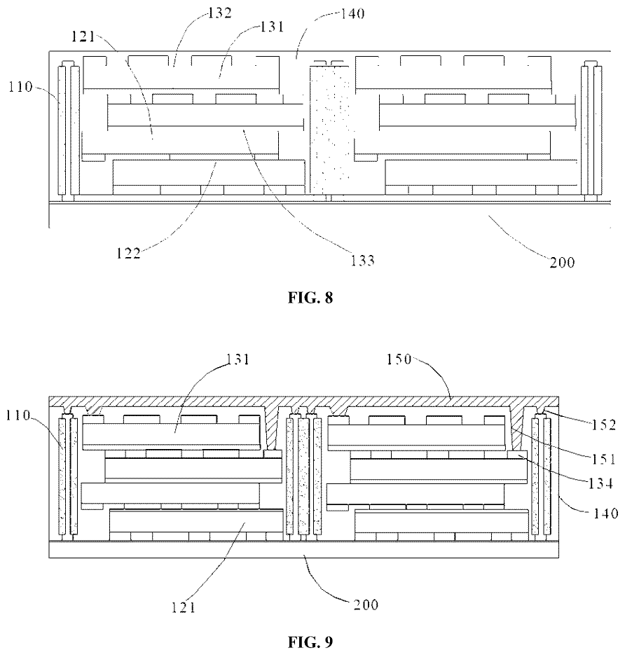

Referring to FIG. 8, the packaging layer 140 coats the first stacking chips 120, the second stacking chips 130, and the pre-supported electrical connection frame 110. Specifically, the packaging layer 140 can be formed on the temporary carrier 200 by using the plastic packaging process. Since the pre-supported electrical connection frame 110 is provided, the plastic packaging material will only flow within the same chip bonding area, so that the flow range and the flow tangential force are smaller, which reduces the impact on the first chip 121 and the second chip 131, and avoids the displacements of the first chip 121 and the second chip 131. Moreover, a height of the packaging layer 140 relative to the temporary carrier 200 is higher than the height of the second chip 131, so that the stacking structure can be covered and protected.

S6: preparing the first redistribution layer 150 on one side of the packaging layer 140, wherein the first redistribution layer 150 is electrically connected to the second chips 131 and one end of the pre-supported electrical connection frame 110.

Referring to FIG. 9, specifically, the thickness of the packaging layer 140 can be adjusted by grinding, so as to achieve planarization. Subsequently, the routing opening can be formed on the surface of the packaging layer 140 by slotting in a patterning method, and the routing opening can expose the conductive pads 114 on the pre-supported electrical connection frame 110 and partial pin pads of the second chips 131. Later, the first redistribution layer 150 is formed by the electroplating process, and the first conductive post 151 and the third conductive post 152 are formed at the same time. Finally, a layer of plastic packaging material is further covered with a protective encapsulation material, so that the first redistribution layer 150 can be protected and isolated from the outside.

Of course, the conductive post and the distribution layer can also be prepared herein by two steps, i.e., the first exposure development opening is performed to expose the target conductive pad 114 and the target pin pads; then the first conductive post 151 and the third conductive post 152 are formed by electroplating; then the routing opening is formed by the exposure development; and then the first redistribution layer 150 is formed by the electroplating.

S7: peeling off the temporary carrier 200 and exposing the other side of the packaging layer 140.

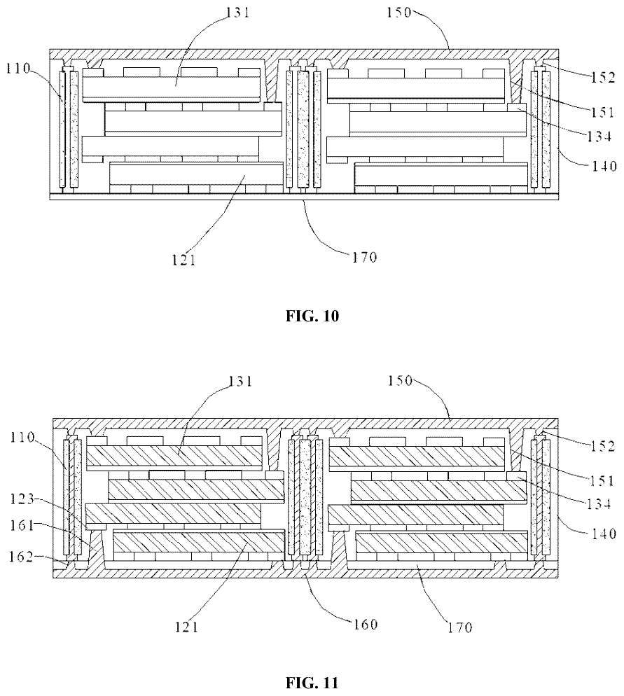

Referring to FIG. 10, specifically, the temporary carrier 200 can be peeled off by unbonding, and the residual adhesive is removed. The surface at one side of the package away from the first redistribution layer 150 is exposed, and at the same time the pin pads of the first chip 121 can be exposed. In order to facilitate the subsequent routing, a layer of photosensitive insulating layer 170 can be covered on the surface of the packaging layer 140 at this time, so as to ensure full coverage the pin pads of the first chip 121.

S8: preparing the second redistribution layer 160 on the other side of the packaging layer 140, wherein the second redistribution layer 160 is electrically connected to the first chips 121 and the other end of the pre-supported electrical connection frame 110.

Referring to FIG. 11, specifically, the routing opening can be formed on the surface of the photosensitive insulating layer 170 by slotting in the patterning method, and the routing opening can expose the conductive pads 114 on the pre-supported electrical connection frame 110 and partial pin pads of the first chips 121. Later, the second redistribution layer 160 is formed by the electroplating process, and the second conductive post 161 and the fourth conductive post 162 are formed at the same time. Finally, a layer of plastic packaging material is further coated, so that the second redistribution layer 160 can be protected and isolated from the outside.

S9: cutting after planting a ball.

Referring to FIG. 1, specifically, tin balls can be formed on the second redistribution layer 160 by ball planting, and then a single product can be obtained by along designated cutting channels.

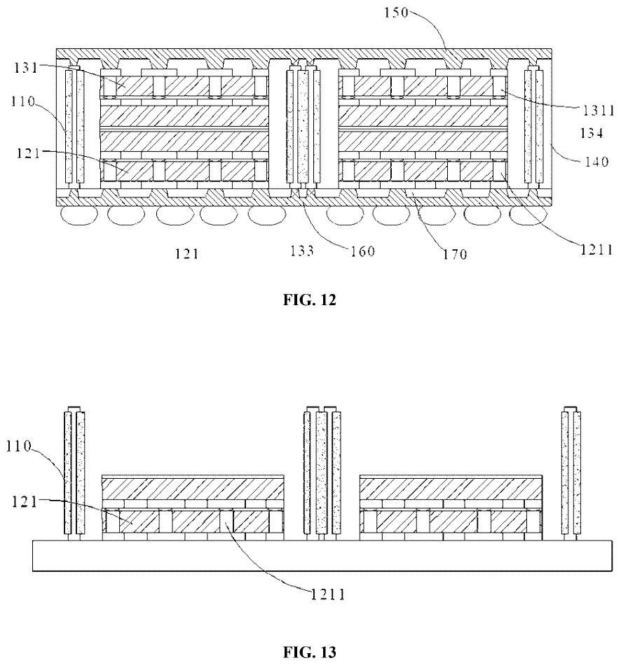

In other preferred embodiments of the present disclosure, referring to FIG. 12, the three-dimensional stacking fan-out packaging device 100 adopts different stacking structures. Specifically, the basic structure and principles and the resulting technical effects are the same as the foregoing embodiments, wherein the differences are that the plurality of first chips 121 are stacked in an aligning manner, and a plurality of first perforated conductive posts 1211 are arranged in the first chips 121 departing from the second chips 131, wherein the first redistribution layer 150 is electrically connected to the first chips 121 by the first perforated conductive posts 1211; and the plurality of second chips 131 are stacked in an aligning manner, and a plurality of second perforated conductive posts 1311 are arranged in the second chips 131 departing from the first chips 121, wherein the second redistribution layer 160 is electrically connected to the second chips 131 by the second perforated conductive posts 1311.

It should be noted that both the first perforated conductive post 1211 and the second perforated conductive post 1311 herein are connected by TSV technology, so as to realize the interconnection of the chips, and at the same time, the chip-to-chip interconnection of the chips can be realized by Micro Bump or Hybrid Bonding.

In other preferred embodiments of the present disclosure, when preparing the three-dimensional stacking fan-out packaging device 100 as described in FIG. 12, the basic steps are as follows (where not mentioned, reference can be made to the relevant descriptions in the steps of the foregoing embodiments).

S1: preparing the pre-supported electrical connection frame 110.

S2: attaching the pre-supported electrical connection frame 110 on the temporary carrier 200.

Specifically, the pre-supported electrical connection frame 110 defines the concave chip bonding area on the temporary carrier 200.

The step S1 and step S2 are the same as that of the foregoing embodiment.

S3: aligning and stacking the functional surfaces of the plurality of first chips 121 on the chip bonding area towards the first direction, so as to form at least one group of the first stacking chips 120.

Referring to FIG. 13, specifically, two first chips 121 can be aligned and stacked on the temporary carrier, wherein the first perforated conductive post 1211 is formed on one of the two first chips 121 at the bottom side by the TSV technology. The chip-to-chip interconnection of the first chips 121 can be realized by the Micro Bump or the Hybrid Bonding.

S4: staggering and stacking the functional surfaces of the plurality of second chips 131 on the first stacking chips 120 towards the second direction, so as to form at least one group of the second stacking chips.

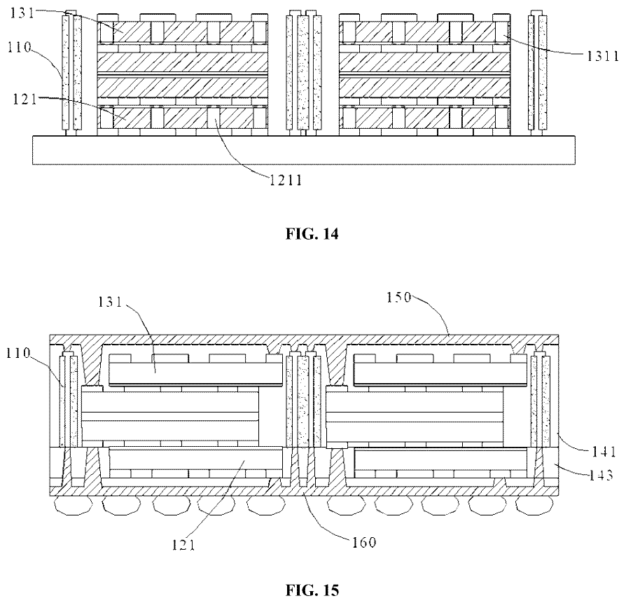

Referring to FIG. 14, specifically, two second chips 131 can be aligned and stacked on the first stacking chip 120, wherein the second perforated conductive post 1211 is formed on one of the two second chip 131 at the top side by the TSV technology. The chip-to-chip interconnection of the second chips 131 can be realized by the Micro Bump or the Hybrid Bonding.

S5: forming the packaging layer 140 on the temporary carrier 200 by plastic packaging.

S6: preparing the first redistribution layer 150 on one side of the packaging layer 140, wherein the first redistribution layer 150 is electrically connected to the second chips 131 and one end of the pre-supported electrical connection frame 110.

S7: peeling off the temporary carrier 200 and exposing the other side of the packaging layer 140.

S8: cutting after planting a ball.

The step S5-step S8 are substantially the same as that of the foregoing embodiment.

In other preferred embodiments of the present disclosure, referring to FIG. 15, the three-dimensional stacking fan-out packaging device 100 adopts different stacking structures. Specifically, the basic structure and principles and the resulting technical effects are the same as the foregoing embodiments, wherein the differences are that the packaging layer 140 includes a primary molding layer 141 and a secondary molding layer 143, wherein the primary molding layer 141 coats the second stacking chip 130, the pre-supported electrical connection frame 110, and a part of the first stacking chip 120, and the first redistribution layer 150 is arranged to one side of the primary molding layer 141; and the secondary molding layer 143 is arranged on the other side of the primary molding layers 141 and coats the rest of the first stacking chip 120, wherein the second redistribution layer 160 is arranged on one side of the secondary molding layer 143 away from the primary molding layer 141.

In some embodiments, a chip size of the first chip 121 located in the secondary molding layer 143 is larger than a chip size of the first chip 121 located in the primary molding layer 141. The first chip 121 in the secondary molding layer 143 is prepared by using a post-packaging process, so that it is not limited by the position of the pre-supported electrical connection frame 110. Therefore, the first chip 121 in the secondary molding layer 143 can be a chip with a larger size, such as a control chip.

In other preferred embodiments of the present disclosure, when preparing the three-dimensional stacking fan-out packaging device 100 as described in FIG. 15, the basic steps are as follows (where not mentioned, reference can be made to the relevant descriptions in the steps of the foregoing embodiments).

S1: preparing the pre-supported electrical connection frame 110.

S2: attaching the pre-supported electrical connection frame 110 on the temporary carrier 200.

Specifically, the pre-supported electrical connection frame 110 defines the concave chip bonding area on the temporary carrier 200.

The step S1 and step S2 are the same as that of the foregoing embodiment.

S3: stacking the functional surfaces of at least the first chips 121 on the chip bonding area towards the first direction.

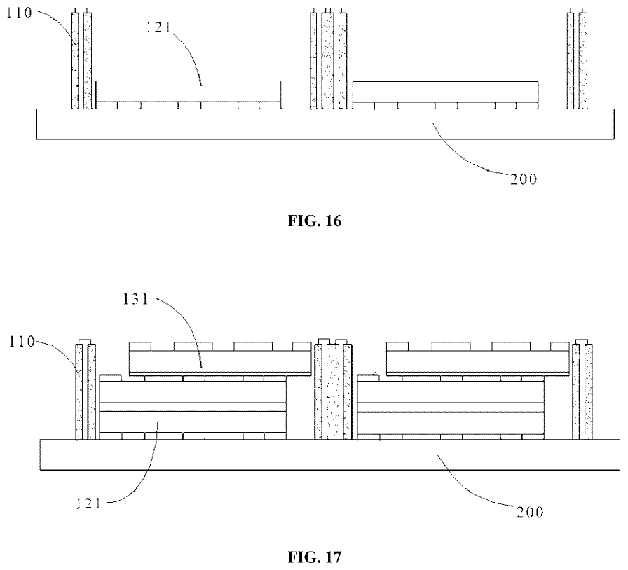

Referring to FIG. 16, specifically, the functional surface of one first chip 121 can be attached downwards to the temporary carrier 200 herein.

S4: stacking the functional surfaces of the plurality of second chips 131 on the first chip 121 towards the second direction.

Referring to FIG. 17, specifically, for example, two second chips 131 are provided. The functional surfaces of the two second chips 131 are attached upwards to the back side of the first chip 121, so as to form the second stacking chip 130.

The first direction and the second direction are opposite, and the second stacking chip 130 and the first stacking chip 120 are arranged in the central symmetry or plane symmetry.

S5: forming the primary molding layer 141 on the temporary carrier by the plastic packaging.

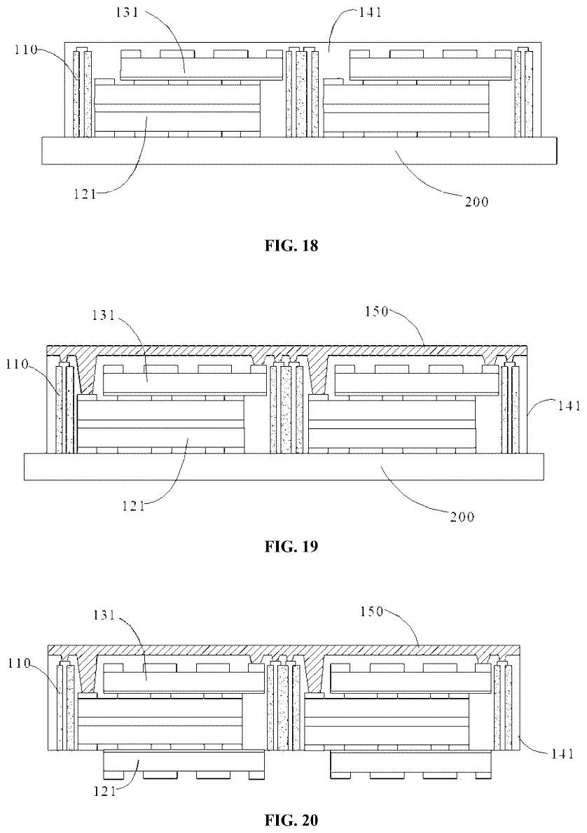

Referring to FIG. 18, the primary molding layer 141 coats the second chip 131, the pre-supported electrical connection frame 110, and the first chip 121.

S6: preparing the first redistribution layer 150 on one side of the primary molding layer 141.

Referring to FIG. 19, the first redistribution layer 150 is electrically connected to the second chip 131 and one end of the pre-supported electrical connection frame 110.

S7: peeling off the temporary carrier 200 and exposing the other side of the primary molding layer 141.

Specifically, after removing the temporary carrier 200, the primary molding layer 141 can be exposed, and at the same time the first chip 121 is coated in a layer of insulating material.

S8: attaching at least one additional first chip 121 on the other side of the primary molding layer 141.

Referring to FIG. 20, specifically, the functional surface of the other first chip 121 is attached downwards on the surface of the primary molding layer, so that two first chips 121 are stacked to form the first stacking chip 120.

S9: forming the secondary molding layer 143 on the other side of the primary molding layer 141.

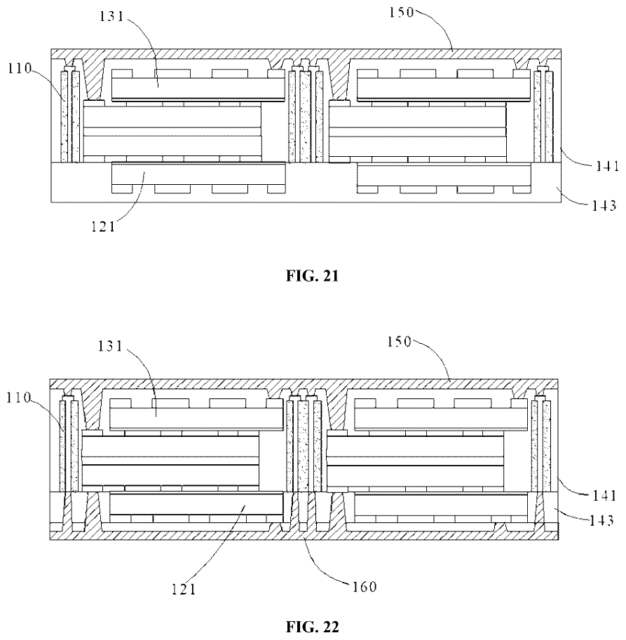

Referring to FIG. 21, the secondary molding layer 143 is coated outside the first chip 121; and the secondary molding layer 143 can be selected from the same plastic packaging material as the primary molding layer 141.

S10: forming the secondary redistribution layer 160 on one side of the second molding layer 143 away from the primary molding layer 141.

Referring to FIG. 22, the second redistribution layer 160 is electrically connected to the first chips 121 and the other end of the pre-supported electrical connection frame 110. It should be noted that when forming the second redistribution layer 160, the secondary molding layer 143 further needs to be slotted, so as to form the second conductive post 161 and the fourth conductive post 162.

S11: ball attachment and subsequent dicing.

Referring to FIG. 15, specifically, the tin balls can be formed on the second redistribution layer 160 by ball planting, and then the single product can be obtained by cutting along the cut channel.

In some other embodiments, after the step S8 is completed, the second conductive post 161 and the fourth conductive post 162 can be prepared in advance. Specifically, after the step S8, the method further includes the following steps.

S9: forming the second conductive post 161 and the fourth conductive post 162 on the primary molding layer 141 and the functional surface of the first chip 121.

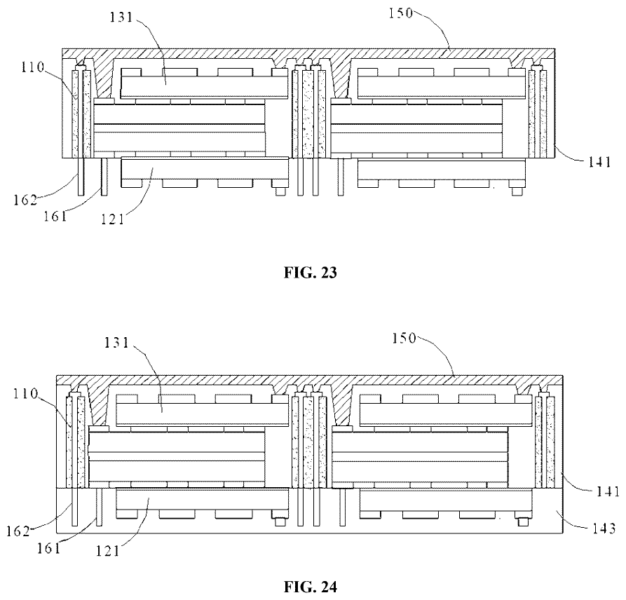

Referring to FIG. 23, specifically, the advance preparation of the bumps can be completed on the primary molding layer 141 and the functional surface of the first chip 121, so as to form the second conductive post 161 and the fourth conductive post 162 in advance, as shown in FIG. 22.

S10: forming the secondary molding layer 143 on the opposite side of the primary molding layer 141.

Referring to FIG. 24, the secondary molding layer 143 encapsulates the first chip 121, the second conductive post 161, and the fourth conductive post 162.

S11: thinning the secondary molding layer 143.

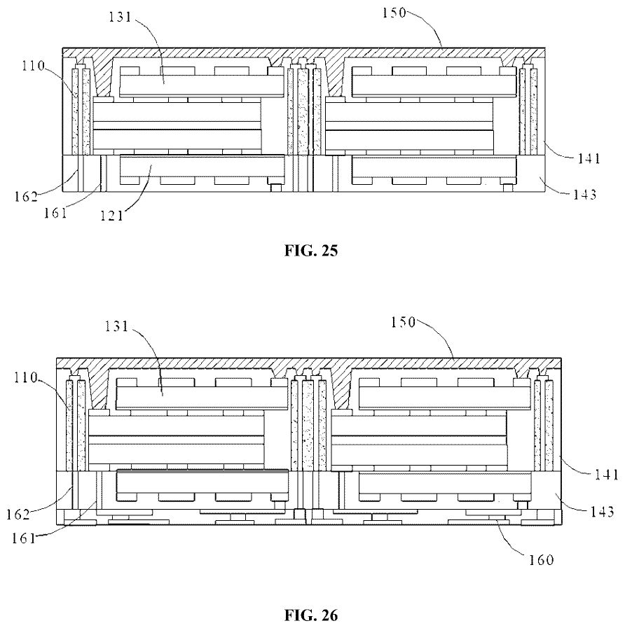

Referring to FIG. 25, specifically, the secondary molding layer 143 is thinned by a grinding process, and the second conductive post 161 and the fourth conductive post 162 are exposed.

S12: forming the secondary redistribution layer 160 on one side of the second molding layer 143 away from the primary molding layer 141.

Referring to FIG. 26, since the second conductive post 161 and the fourth conductive post 162 have been prepared in advance, it can be routed without slotting again, and the second redistribution layer 160 is connected to the second conductive post 161 and the fourth conductive post 162 at the same time.

S13: cutting after planting the ball.

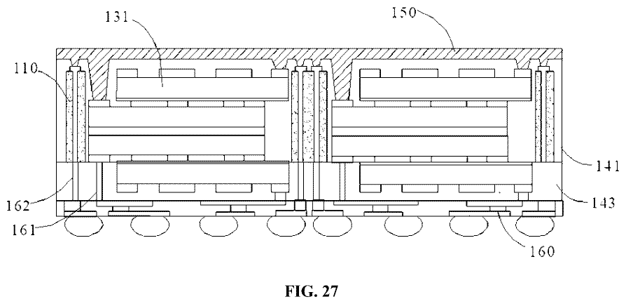

Referring to FIG. 27, the ball planting is completed finally and the solder balls are formed.

In summary, the three-dimensional stacking fan-out packaging device 100 and the preparation method therefor provided by the embodiments of the present disclosure define the concave chip bonding area by using the pre-supported electrical connection frame 110; at least one group of first stacking chips 120 are arranged in the chip bonding area, wherein the first stacking chips 120 include the plurality of first chips 121 with functional surfaces towards the first direction, and the plurality of first chips 121 are staggered and stacked; and at the same time, the second stacking chip 130 is stacked on the first stacking chips 120, wherein the second stacking chip 130 includes the plurality of second chips 131 with functional surfaces towards the second direction, and the plurality of second chips 131 are staggered and stacked. Later, after the packaging is finished by using the packaging layer 140, the routing is completed on two sides of the packaging layer 140, so as to form the first redistribution layer 150 and the second redistribution layer 160. The first redistribution layer 150 is electrically connected to the second chips 131; the second redistribution layer 160 is electrically connected to the first chips 121; and the first redistribution layer 150 and the second redistribution layer 160 are electrically connected by the pre-supported electrical connection frame 110, so as to realize the integral electrical connection. Moreover, the first stacking chip and the second stacking chip 130 are arranged in the central symmetry or plane symmetry. Compared to the prior art, the embodiments of the present disclosure provide the three-dimensional stacking fan-out packaging device 100, wherein the first redistribution layer 150 is connected to the second redistribution layer 160 by using the pre-supported electrical connection frame 110, which can realize the routing interconnection without using the method of forming the conductive post by on site slotting and electroplating, which significantly reduces the cost and improves the yield. Meanwhile, the symmetric coreless RDL structure is used with a very high chip proportion; and the warpage is controlled very well, which can significantly solve the problem of warpage during the preparation process. It not only can greatly improve the yield and reliability when performing the wafer-level packaging, but also can directly implement Fine Pitch RDL, which can meet the needs of High IO and high density. It will have advantages in the future Chiplet packaging, and can expand more applications on products.

The foregoing is only specific embodiments of the present disclosure, but the scope of protection of the present disclosure is not limited thereto. Any modifications or replacements that can easily be thought of by a person familiar with the technical field within the technical scope disclosed by the present disclosure, shall be covered by the protection scope of the present disclosure. Therefore, the scope of protection of the present disclosure shall be governed by the scope of protection of the claims.

1. A three-dimensional stacking fan-out packaging device, comprising:
a pre-supported electrical connection frame, wherein the pre-supported electrical connection frame is configured to define a chip bonding area;
at least one group of first stacking chips arranged in the chip bonding area, wherein each group of the first stacking chips comprise a plurality of first chips with functional surfaces facing a first direction;
at least one group of second stacking chips stacked on the first stacking chips, wherein each group of the second stacking chips comprise a plurality of second chips with functional surfaces facing a second direction;
a packaging layer, wherein the packaging layer coats the first stacking chips, the second stacking chips, and the pre-supported electrical connection frame;
a first redistribution layer, wherein the first redistribution layer is located on one side of the packaging layer, and is electrically connected to the second chips and one end of the pre-supported electrical connection frame; and
a second redistribution layer, wherein the second redistribution layer is located on the other side of the packaging layer, and is electrically connected to the first chips and the other end of the pre-supported electrical connection frame, wherein
amounts of the first chips and the second chips are the same; the first direction and the second direction are opposite; the second stacking chips and the first stacking chips are arranged in a central symmetry or plane symmetry; and the first redistribution layer and the second redistribution layer are electrically connected by the pre-supported electrical connection frame.

2. The three-dimensional stacking fan-out packaging device according to claim 1, wherein the plurality of first chips are staggered and stacked, and the plurality of second chips are staggered and stacked.

3. The three-dimensional stacking fan-out packaging device according to claim 2, wherein in each adjacent two of the first chips, a first chip departing from the second direction is arranged in a staggered manner in a third direction relative to the other first chip; and
in each adjacent two of the second chips, a second chip departing from the second direction is arranged in the staggered manner in the third direction or a fourth direction relative to the other second chip, wherein
the third direction is opposite to the fourth direction.

4. The three-dimensional stacking fan-out packaging device according to claim 3, wherein non-functional surfaces of adjacent first chip and second chip are attached to each other, and the second chip is arranged relative to the adjacent first chip in the staggered manner in the fourth direction.

5. The three-dimensional stacking fan-out packaging device according to claim 3, wherein non-functional surfaces of adjacent first chip and second chip are attached to each other, and the second chip is attached relative to the adjacent first chip in an aligning manner.

6. The three-dimensional stacking fan-out packaging device according to claim 3, wherein non-functional surfaces of adjacent first chip and second chip are attached to each other, and the second chip is arranged relative to the adjacent first chip in the staggered manner in the third direction.

7. The three-dimensional stacking fan-out packaging device according to claim 2, wherein the packaging layer comprises a primary molding layer and a secondary molding layer, and the primary molding layer coats the second stacking chips, the pre-supported electrical connection frame, and a part of the first stacking chips, wherein the first redistribution layer is arranged to one side of the primary molding layer; the secondary molding layer is arranged on the other side of the primary molding layer and coats the rest of the first stacking chips; and the second redistribution layer is arranged on one side of the secondary molding layer away from the primary molding layer.

8. The three-dimensional stacking fan-out packaging device according to claim 7, wherein chip sizes of the first chips located in the secondary molding layer are larger than chip sizes of the first chips located in the primary molding layer.

9. The three-dimensional stacking fan-out packaging device according to claim 2, wherein adjacent first chips are attached by a first die attach film; adjacent second chips are attached by a second die attach film; and adjacent first chip and second chip are attached by a third die attach film.

10. The three-dimensional stacking fan-out packaging device according to claim 2, wherein first pin pads are arranged on all functional surfaces of the plurality of first chips, wherein at least one of the first pin pads of each of the first chips is configured not to be obscured in the first direction by the other first chips, and the second redistribution layer is electrically connected to the first pin pads; and
second pin pads are arranged on all functional surfaces of the plurality of second chips, wherein at least one of the second pin pads of each of the second chips is configured not to be obscured in the second direction by the other second chips, and the first redistribution layer is electrically connected to the second pin pads.

11. The three-dimensional stacking fan-out packaging device according to claim 10, wherein a plurality of first conductive posts raised towards the second direction are arranged on the first redistribution layer, and the plurality of first conductive posts are connected to the second pin pads on the plurality of second chips; and
a plurality of second conductive posts raised towards the first direction are arranged on the second redistribution layer, and the second conductive posts are connected to the first pin pads on the plurality of first chips.

12. The three-dimensional stacking fan-out packaging device according to claim 2, wherein the three-dimensional stacking fan-out packaging device further comprises a photosensitive insulating layer arranged between the packaging layer and the second redistribution layer.

13. The three-dimensional stacking fan-out packaging device according to claim 2, wherein a third conductive post raised towards the second direction is further arranged on the first redistribution layer, and the third conductive post is connected to one end of the pre-supported electrical connection frame; and a fourth conductive post raised towards the first direction is further arranged on the second redistribution layer, and the fourth conductive post is connected to the other end of the pre-supported electrical connection frame.

14. The three-dimensional stacking fan-out packaging device according to claim 1, wherein the pre-supported electrical connection frame comprises:
a carrier filling enclosure, wherein the carrier filling enclosure is configured to define a chip attachment area, and a plated through hole is formed by passing through the carrier filling enclosure; and
a filling conductive post, wherein the filling conductive post is filled in the plated through hole, and conductive pads are formed on two ends of the filling conductive post.

15. The three-dimensional stacking fan-out packaging device according to claim 14, wherein a height of the carrier filling enclosure in the second direction is shorter than or equal to a stacking height of the first stacking chips and the second stacking chips.

16. The three-dimensional stacking fan-out packaging device according to claim 1, wherein the plurality of first chips are stacked in an aligning manner, and a plurality of first perforated conductive posts are arranged in the first chips departing from the second chips, wherein the first redistribution layer is electrically connected to the first chips by the first perforated conductive posts; and
the plurality of second chips are stacked in the aligning manner, and a plurality of second perforated conductive posts are arranged in the second chips departing from the first chips, wherein the second redistribution layer is electrically connected to the second chips by the second perforated conductive posts.

17. A preparation method for a three-dimensional stacking fan-out packaging device, for preparing the three-dimensional stacking fan-out packaging device according to claim 1, wherein the preparation method comprises:
preparing the pre-supported electrical connection frame;
attaching the pre-supported electrical connection frame on a temporary carrier, so that the pre-supported electrical connection frame defines a concave chip bonding area on the temporary carrier;
stacking functional surfaces of the plurality of first chips on the chip bonding area towards the first direction, so as to form at least one group of the first stacking chips;
stacking functional surfaces of the plurality of second chips on the first stacking chips towards a second direction, so as to form at least one group of the second stacking chips;
forming the packaging layer on the temporary carrier by plastic packaging, wherein the packaging layer coats the first stacking chips, the second stacking chips, and the pre-supported electrical connection frame;
preparing the first redistribution layer on one side of the packaging layer, wherein the first redistribution layer is electrically connected to the second chips and one end of the pre-supported electrical connection frame; and
peeling off the temporary carrier and exposing the other side of the packaging layer; and
preparing the second redistribution layer on the other side of the packaging layer, wherein the second redistribution layer is electrically connected to the first chips and the other end of the pre-supported electrical connection frame, wherein
the first direction and the second direction are opposite, and the second stacking chips and the first stacking chips are arranged in a central symmetry or plane symmetry.

18. The preparation method for the three-dimensional stacking fan-out packaging device according to claim 17, wherein the step of preparing the pre-supported electrical connection frame comprises:
providing a molding material;
forming a plated through hole by passing through the molding material;
filling an electroplated metal or a conductive resin in the plated through hole to form a filling conductive post;
forming conductive pads on two ends of the filling conductive post; and
removing a middle region of the molding material.

19. A preparation method for the three-dimensional stacking fan-out packaging device, for preparing the three-dimensional stacking fan-out packaging device according to claim 15, wherein the preparation method comprises:
preparing the pre-supported electrical connection frame;
attaching the pre-supported electrical connection frame on a temporary carrier, so that the pre-supported electrical connection frame defines a concave chip bonding area on the temporary carrier;
stacking functional surfaces of at least the first chips on the chip bonding area towards the first direction;
stacking functional surfaces of the plurality of second chips on the first chips towards a second direction, so as to form the second stacking chips;
forming a primary molding layer on the temporary carrier by plastic packaging, wherein the primary molding layer coats the second chips, the pre-supported electrical connection frame, and the first chips;
preparing the first redistribution layer on one side of the primary molding layer, wherein the first redistribution layer is electrically connected to the second chips and one end of the pre-supported electrical connection frame;
peeling off the temporary carrier and exposing the other side of the primary molding layer;
attaching at least one first chip on the other side of the primary molding layer, so that the first stacking chips are formed by stacking the plurality of first chips;
forming a secondary molding layer on the other side of the primary molding layer, wherein the secondary molding layer is coated outside the first chips; and
forming the secondary redistribution layer on one side of the second molding layer away from the primary molding layer, wherein the second redistribution layer is electrically connected to the first chips and the other end of the pre-supported electrical connection frame, wherein the first direction and the second direction are opposite, and the second stacking chip and the first stacking chip are arranged in a central symmetry or plane symmetry.

20. The preparation method for the three-dimensional stacking fan-out packaging device according to claim 17, wherein the plurality of first chips are staggered and stacked, and the plurality of second chips are staggered and stacked.
